(19) United States
(12) Patent Application Publication
(10) Pub. No.: US 2010/0301321 A1
(43) Pub. Date: Dec. 2, 2010

(54) Tunable Diode

(75) Inventors: Michael S. Freund, Winnipeg (CA); Jun Hui Zhao, Winnipeg (CA); G.M. Aminur Rahman, Winnipeg (CA); Douglas J. Thomson, Winnipeg (CA)

Correspondence Address: FULBRIGHT & JAWORSKI L.L.P., 600 CONGRESS AVE., SUITE 2400, AUSTIN, TX, 78701, US

(73) Assignee: UNIVERSITY OF MANITOBA

(21) Appl. No.: 12/790,371

(22) Filed: May 28, 2010

Related U.S. Application Data
(60) Provisional application No. 61/182,013, filed on May 28, 2009.

(51) Int. Cl. H01L 51/05; H01L 51/40

(52) U.S. Cl. 257/40; 438/99; 438/466; 257/E51.027; 257/E51.011

(57) ABSTRACT

Tunable diodes and methods of making.

### CROSS REFERENCE TO RELATED APPLICATIONS

This application claims priority to U.S. Provisional Application No. 61/182,013 filed May 28, 2009, which is specifically incorporated by reference in its entirety without disclaimer.

### BACKGROUND

1. Field of the Invention

The present invention relates generally to junctions for electronic applications, and, more particularly, but not by way of limitation, to conjugated polymer, metal oxide-based tunable heterojunctions for electronic applications such as diodes.

2. Description of Related Art

A number of junctions (and diodes with such junctions) have been developed and/or are in use in the art. Many previously known diodes are manufactured with a fixed physical and/or chemical configuration (and resulting properties), such that separate manufacturing equipment and/or equipment configurations may be required to produce diodes having different properties. Examples of properties that may be fixed according to the physical and/or chemical configuration of a typical diode include Fermi level, threshold voltage, and on/off current. Specific manufacturing equipment and/or equipment configurations that may be required for specific designs of diodes (or other junctions or devices with a junction) can make it expensive to manufacture different diode designs and/or to accommodate changes in diode design in manufacturing processes or equipment.

As device features approach and/or are reduced into the sub 100 nanometer (nm) size, conventional semiconductor manufacturing methods may face increasing technological difficulties. The decreased size can result in large variances in device characteristics, and may affect key parameters such as threshold voltage and on/off current. Attempts at smaller solutions to these difficulties may, for example, have a physical size, programming voltage, and/or programming current that is excessive for high density systems at the 65 nm node and beyond.

### SUMMARY

The present disclosure includes various embodiments of tunable diodes (and other heterojunction devices) and methods of making diodes (and other heterojunction devices).

Some embodiments of the present tunable diodes comprise: a first material configured to be dopable electrochemically, the first material comprising an anion and a cation, where one of the anion and cation is immobile, and the other of the anion and cation is mobile; a second material coupled to the first material, the second material configured to be dopable electrochemically; where the first material and second material are configured such that if a sufficient voltage potential is applied across the first material and second material: (1) at least a portion of the mobile one of the anion and cation migrates from the first material to the second material such that p-doping of one of the first and second materials increases and n-doping of the other of the first and second materials increases; and (2) the conductivity increases across the coupled first and second materials.

In some embodiments, the first material comprises a semiconducting polymer. In some embodiments, the semiconducting polymer is an organic polymer. In some embodiments, the second material comprises an oxide. In some of these embodiments, the oxide comprise tungsten oxide (WO₃). In some embodiments, the anion is immobile and comprises DS⁻. In some embodiments, the cation is mobile and comprises Li⁺.

In some embodiments, the semiconducting polymer comprises polypyrrole (PPy). In some embodiments, the anion is immobile and comprises dodecyl benzene sulfonate (DBS). In some embodiments, the cation is mobile and comprises lithium (Li⁺).

In some embodiments, the second material is in contact with the first material.

In some embodiments, at least one of the first and second materials is not doped in the absence of a voltage potential. In some embodiments, both of the first and second materials are not doped in the absence of a voltage potential. In some embodiments, one of the first and second materials is p-doped in the absence of a voltage potential. In some embodiments, one of the first and second materials is n-doped in the absence of a voltage potential. In some embodiments, the other the other of the first and second materials is p-doped in the absence of a voltage potential.

Some embodiments of the present methods of making a tunable diode comprise: providing a first material configured to be dopable electrochemically, the first material comprising an anion and a cation, where one of the anion and cation is immobile, and the other of the anion and cation is mobile; immersing the first material in a liquid solution; applying a first tuning voltage potential across the first material while the first material is immersed in the solution, the first tuning voltage potential sufficient to modify the electrochemical potential of the first material; providing a second material configured to be dopable electrochemically; coupling the first material to the second material such that if a sufficient voltage potential is applied across the coupled first and second materials: (1) at least a portion of the mobile one of the anion and cation migrates from the first material to the second material such that p-doping of one of the first and second materials increases and n-doping of the other of the first and second materials increases; and (2) the conductivity increases across the coupled first and second materials.

In some embodiments, the first material comprises a semiconducting polymer. In some embodiments, the semiconducting polymer is an organic polymer. In some embodiments, the second material comprises an oxide. In some of these embodiments, the oxide comprise tungsten oxide (WO₃). In some embodiments, the anion is immobile and comprises DS⁻. In some embodiments, the cation is mobile and comprises Li⁺.

In some embodiments, the semiconducting polymer comprises polypyrrole (PPy). In some embodiments, the anion is immobile and comprises dodecyl benzene sulfonate (DBS). In some embodiments, the cation is mobile and comprises lithium (Li⁺).

In some embodiments, the solution comprises the mobile one of the anion and cation. In some embodiments, the solution comprises lithium (Li). In some embodiments, the solution comprises lithium perclorate (LiClO₄). In some embodiments, the solution comprises propylene carbonate.

In some embodiments, in the coupling, the second material is coupled to the first material such that the second material is in contact with the first material. In some embodiments, the coupling is performed prior to immersing or applying a voltage to the first material.

Some embodiments further comprise: immersing the second material in a liquid solution; and applying a second tuning voltage potential across the second material while the second material is immersed in the solution, the second tuning voltage potential sufficient to modify the electrochemical potential of the second material. In some embodiments, the coupling is performed prior to immersing or applying a voltage to either of the first material or the second material. In some embodiments, after applying the tuning voltage potential across the first and second materials, at least one of the first and second materials is not doped in the absence of a voltage potential. In some embodiments, after applying the first tuning voltage potential across the first material and applying the second tuning voltage potential across the second material, neither of the first and second materials is not doped in the absence of a voltage potential. In some embodiments, after applying the first tuning voltage potential across the first material and applying the second tuning voltage potential across the second material, one of the first and second materials is p-doped in the absence of a voltage potential. In some embodiments, after applying the first tuning voltage potential across the first material and applying the second tuning voltage potential across the second material, one of the first and second materials is n-doped in the absence of a voltage potential. In some embodiments, after the first tuning voltage potential across the first material and applying the second tuning voltage potential across the second material, the other of the first and second materials is p-doped in the absence of a voltage potential. In some embodiments, the magnitude of the first tuning voltage potential is equal to the magnitude of the second tuning voltage potential. In some embodiments, the first tuning voltage potential is equal to the second tuning voltage potential.

Some embodiments of the present methods comprise: providing a first material configured to be dopable electrochemically, the first material comprising an anion and a cation, where one of the anion and cation is immobile, and the other of the anion and cation is mobile; providing a second material configured to be dopable electrochemically; immersing the second material in a liquid solution; applying a second tuning voltage potential across the second material while the second material is immersed in the solution, the second tuning voltage potential sufficient to modify the electrochemical potential of the second material; and coupling the first material to the second material such that if a sufficient voltage potential is applied across the coupled first and second materials: (1) at least a portion of the mobile one of the anion and cation migrates from the first material to the second material such that p-doping of one of the first and second materials increases and n-doping of the other of the first and second materials increases; and (2) the conductivity increases across the coupled first and second materials.

Some embodiments of the present methods comprise: providing a first material configured to be dopable electrochemically, the first material comprising an anion and a cation, where one of the anion and cation is immobile, and the other of the anion and cation is mobile; providing a second material configured to be dopable electrochemically; coupling the first material to the second material such that if a sufficient voltage potential is applied across the coupled first and second materials: (1) at least a portion of the mobile one of the anion and cation migrates from the first material to the second material such that p-doping of one of the first and second materials increases and n-doping of the other of the first and second materials increases; and (2) the conductivity increases across the coupled first and second materials.

Some embodiments of the present tunable diodes are made by the various embodiments of the methods herein.

Any embodiment of any of the present methods can consist of or consist essentially of—rather than comprise/include/contain/have—any of the described steps, elements, and/or features. Thus, in any of the claims, the term “consisting of” or “consisting essentially of” can be substituted for any of the open-ended linking verbs recited above, in order to change the scope of a given claim from what it would otherwise be using the open-ended linking verb.

Details associated with the embodiments described above and others are presented below.

### BRIEF DESCRIPTION OF THE DRAWINGS

The following drawings illustrate by way of example and not limitation. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers.

FIG. 1 depicts one embodiment of the present diodes.

FIG. 2 depicts one embodiment of a method for making the present diodes.

FIG. 3 depicts current density behavior of PT⁺(DS⁻) composite on an interdigital array (IDA) electrode in the oxidized state as grown prior to reduction, and after reduction with Li⁺ incorporated in the film.

FIG. 4 depicts multi-potential steps curves of PT⁺(DS⁻) on an IDA electrode.

FIG. 5 depicts charging and discharging properties of a PT(Li⁺DS⁻)|WO₃ heterojunction in 0.1M LiClO₄ in propylene carbonate solution.

FIG. 6 depicts the voltammetric response of PT⁺(DS⁻) and WO₃ thin films on ITO electrodes immersed in 0.1 M LiClO₄ propylene carbonate solution.

FIG. 7 depicts current passing through a PT(Li⁺DS⁻)|WO₃ heterojunction in direct contact under nitrogen, and without direct contact (in 0.1 M LiClO₄ in propylene carbonate solution.

FIG. 8 depicts the temporal behavior of a PT(Li⁺DS⁻)|WO₃ heterojunction due to drifting of Li⁺ across the junction in contact in solid-state, and with no contact in 0.1M LiClO₄ propylene carbonate solution.

FIG. 9 depicts current density as a function of applied bias for a PT(Li⁺DS⁻)|WO₃ sandwich structure in contact.

FIG. 10 depicts current density behavior of a PT(Li⁺DS⁻) WO₃ tunable diode.

FIG. 11 depicts UV-visible spectra of (a) PT⁺(DS⁻) film subjected to oxidizing positive potentials, and (b) WO₃ film subjected to reducing negative potentials.

FIG. 12 depicts UV-visible spectra of a sandwich film of PT(Li⁺DS⁻)|WO₃ under different potentials.

### DESCRIPTION OF ILLUSTRATIVE EMBODIMENTS

The term “coupled” is defined as connected, although not necessarily directly, and not necessarily mechanically; two items that are “coupled” may be integral with each other. The terms “a” and “an” are defined as one or more unless this disclosure explicitly requires otherwise. The terms “substantially,” “approximately,” and “about” are defined as largely but not necessarily wholly what is specified, as understood by a person of ordinary skill in the art.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those elements. Likewise, a method that “comprises,” “has,” “includes” or “contains” one or more steps possesses those one or more steps, but is not limited to possessing only those one or more steps. For example, in a method that comprises providing a first material providing a second material, and coupling the first material to the second material, the method includes the specified steps but is not limited to having only those steps. For example, such a method could also include immersing the first material in a solution, and applying a first tuning voltage potential to the first material while it is immersed in the solution; before or after coupling the first material to the second material.

Further, a device or structure that is configured in a certain way is configured in at least that way, but it can also be configured in other ways than those specifically described.

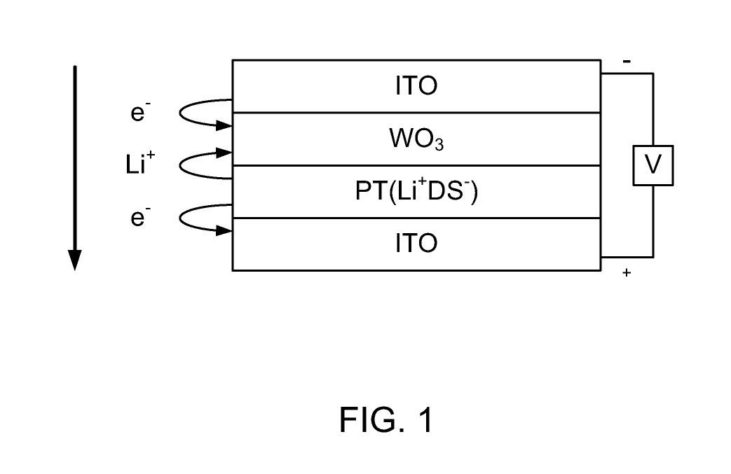

Referring now to the drawings, and more particularly to FIG. 1, shown therein and designated by the reference numeral 10 is an embodiment of the present diodes. Diode 10 may also be referred to herein as heterojunction 10. Diode 10 exhibits rectifying function similar to a traditional p/n junction. In the embodiment shown, diode 10 comprises a first material 14, a second material 18, and two electrodes 22. First material 14 and second material 18 are configured to be dopable electrochemically. As used herein, dopable means that a material can be made p-doped (have an excess or unbalanced level of electron holes) or n-doped (have an excess or unbalanced level of electrons). In the embodiment shown, first material 14 and second material 18 are in a layered configuration, and may interchangeably be referred to herein as first layer 14 and second layer 18, respectively. As also shown, first material 14 is coupled to (e.g., in contact with) second material 18, one electrode 22 is coupled to first material 14, and the other electrode 22 is coupled to second material 18. Diode 10 is also shown coupled to a power source 26, which may, for example, be a battery or any other suitable power source. In the embodiment shown (and as indicated by the respective symbols), the electrode that is coupled to first material 14 is a negative (−) electrode (is connected to the negative pole of the power source), and the electrode that is coupled to second material 18 is a positive (+) electrode (is in contact with the positive pole of the power source). In other embodiments, the electrode coupled to first material 14 can be a positive (+) electrode, and the electrode coupled to second material 18 can be a negative (−) electrode.

First material 14 can comprise a semiconducting polymer such as a conjugated polymer (e.g., an organic polymer). In the embodiment shown, first material 14 comprises polythiophene (PT). In other embodiments, the first material can comprise conductive polymers or mixtures of conductive polymers such as polypyrrole (PPy), polyacetylene (PA), polythiophene (PT), polyaniline, polyphenylene (PPP), poly(phenylene vinylene) and/or derivatives thereof. First material 14 further comprises an anion and a cation. One of the anion and cation is immobile (e.g., has a molecular size and/or shape that does not permit migration within or out of the first material), and the other of the anion and cation is mobile (e.g., has a molecular size and/or shape that permits migration within and/or out of the material). Although the singular forms of anion and cation are used, this refers to the type of anions and cations (e.g., Li⁺ is a single type of cation), and it should be understood that many individual anions and cations will generally be present (e.g., many DS⁻ anions and many Li⁺ cations). In the embodiment shown, the cation is mobile and comprises lithium (Li⁺). In other embodiments, the cation can be immobile and/or can comprise any other suitable element, such as, for example, sodium (Na⁺). In the embodiment shown, the anion is immobile and comprises DS⁻. In other embodiments, the anion can be immobile and/or can comprise any other suitable element, such as, for example, dodecyl benzene sulfonate (DBS). In the embodiment shown, first material can be described as comprising polythiophene (PT) that includes (or contains) lithium dodecylsulfate (Li⁺DS⁻).

In the embodiment shown, polymeric layer 14 comprises PT(Li⁺DS⁻). PT(Li⁺DS⁻) is a neutral conjugated polymer that has immobile anions and highly mobile cations. In some embodiments, PT(Li⁺DS⁻) is created electrochemically. PT(Li⁺DS⁻) is generally a solid-state conducting polymer hybrid material that exhibits non-linear I-V behavior associated with ion drift. When a field is applied to PT(Li⁺DS⁻) in the solid state (in the absence of an electrolyte solution), cations drift and allow injection of charge carriers (holes), thereby reducing the thickness of the relatively insulating neutral polymer and in turn increasing the field strength within the bulk of the polymer. PT(Li⁺DS⁻) can also release cations upon oxidation. In other embodiments, polymeric layer 14 can comprise any suitable conducting polymer and/or conducting hybrid polymer that exhibits similar properties, such as, for example, those comprising polyacetylene, polyaniline, polypyrrole, polythiophene (PT), and the like.

Some embodiments of conductive polymers that comprise an anion and cation, and that can be suitable for various embodiments of the present invention, are described in R. G. Pillai, J. H. Zhao, M. S. Freund, D. J. Thomson, Adv. Mater. 2008, 20, 49, which is incorporated by reference in its entirety.

Second material 18 is coupled to first material 14. In the embodiment shown, second material 18 is in contact with first material 14. As mentioned above, second material 18 is also configured to be dopable. In some embodiments, second material 18 has a low conductivity. Second material 18 can comprise, for example, an oxide. In the embodiment shown, second material 18 comprises tungsten oxide (WO₃). Tungsten oxide (WO₃) may be known in the art as a wide-bandgap dielectric (the electronic gap of amorphous tungsten oxide is 3.25 eV). A wide range of conductivities have also been reported for tungsten oxide. Tungsten oxide may also have distinct intercalation properties with H⁺, Li⁺, Na⁺ and K⁺ upon reduction. In other embodiments, oxide layer 18 can comprise any suitable material, such as, for example, titanium dioxide (TiO₂) or the like.

In the embodiment shown, electrodes 22 comprise indium tin oxide (ITO, or tin-doped indium oxide). In other embodiments, electrodes 22 can comprise any suitable material, such as, for example, gold or the like.

In this way, the first and second materials are configured such that if a sufficient voltage potential (e.g., at or above the threshold voltage of heterojunction 10) is applied across the first material and second material (e.g, between electrodes 22), at least a portion of the mobile one of the anion and cation will migrate from the first material (14) to the second material (18) such that p-doping of one of the first and second materials increases and n-doping of the other of the first and second materials increases, and such that the conductivity increases across the coupled first and second materials (e.g., between electrodes 22). In the embodiment shown, the first and second materials are configured such that when a voltage potential is applied across the first and second materials (e.g. positive to PT(Li⁺DS⁻) and negative to WO₃), at least a portion of the mobile Li⁺ cation will migrate from the PT(Li⁺DS⁻) to the WO₃ such that the WO₃ becomes p-doped (Li⁺ takes free electrons from the WO3 and thereby creates electron holes) and the PT(Li⁺DS⁻) becomes n-doped (gains excess or free “carrier” electrons).

The threshold voltage of heterojunction 10 can be adjusted or “tuned” by adjusting (e.g., as described in more detail below) the individual properties (e.g., electrochemical potential or doping) of each of first material 14 and second material 18 such as, for example, before or after first and second materials 14 and 18, respectively, are coupled to one another. For example, in some embodiments, at least one (and/or both) of the first and second materials is not doped in the absence of a voltage potential (across the first and second materials between electrodes 22). In the embodiment shown, the positive charge of the Li+ cations in the PT(Li⁺DS⁻) can be offset or balanced by the negative charge of the DS⁻ anions. By way of another example, in some embodiments, one of the first and second materials is p-doped in the absence of a voltage potential. In the embodiment shown, the negative charge of the DS⁻ anions in the PT(Li⁺DS⁻) can be greater in magnitude than the positive charge of the Li⁺ cations, such that the PT(Li⁺DS⁻) is p-doped in the absence of a voltage potential. In such an embodiment, the second material can, additionally or alternatively, be n-doped in the absence of a voltage potential. In other embodiments, the first material can be n-doped and/or the second material p-doped in the absence of a voltage potential.

With sufficient voltage potential across the first and second materials, the field induces the drift of mobile cations (lithium in this case) from the neutral polymer into the neutral tungsten oxide (both resistive) along with the concomitant injection of holes in the polymer, and electrons into the tungsten oxide, thereby creating the doped conducting form of both materials. By adjusting the Fermi level of both the polymer composite and the tungsten oxide in solution prior to operating the junction in the solid state (i.e., under nitrogen or vacuum) the threshold voltage for rectification can be “tuned” or adjusted.

Properties such as Fermi level of first material 14 (e.g., conducting polymer) and/or second material 18 (e.g., oxide) can be adjusted by immersing first material 14 and/or second material 18 in a solution and applying a tuning voltage potential across first material 14 and/or second material 18, respectively. The solution can comprise any suitable solvent, such as, for example, propylene carbonate, water, or the like. The solution can also comprise any suitable solute, such as, for example, the mobile one of the anion and cation in first material 14 (e.g., lithium (Li)). For example, where the cation is mobile and comprises Li⁺, the solution can comprise lithium perclorate (LiClO₄). First material 14 and second material 18 need not both be immersed, or a tuning voltage potential applied, at the same time or in the same solution.

In this way, a p/n junction can be manufactured with desired characteristics, such as, for example, a desired or predetermined threshold voltage, or the like. Such characteristics of a resulting asymmetric heterojunction can be determined or selected, for example, by varying the solution, the bias voltage, period of time for which the bias voltage is applied and heterojunction is immersed in the solution, and/or other characteristics of the process. Additionally, during physical construction of the various layers and/or the entire heterojunction, charge neutrality can be maintained and the asymmetry of the final heterojunction created and/or adjusted by manipulating the cations between the polymeric and oxide layers.

The present polymer-metal oxide based rectifying devices can be manufactured to behave like traditional diodes, with the novel characteristic that the effective barrier height and in turn the threshold voltage can be controlled electrochemically and the performance of the device can be tuned even after physical device fabrication. In this way, such devices can be made to have characteristics that extend and/or combine the range of the effective barrier heights accessible with semiconductor diodes based on WO₃, Ti0₂, and the like.

The PT(Li⁺DS⁻)|WO₃ heterojunction diodes, even beyond these novel device properties, can provide a platform for studying the mechanism of Fermi-level pinning and for probing the details of electron transfer at semiconducting interfaces.

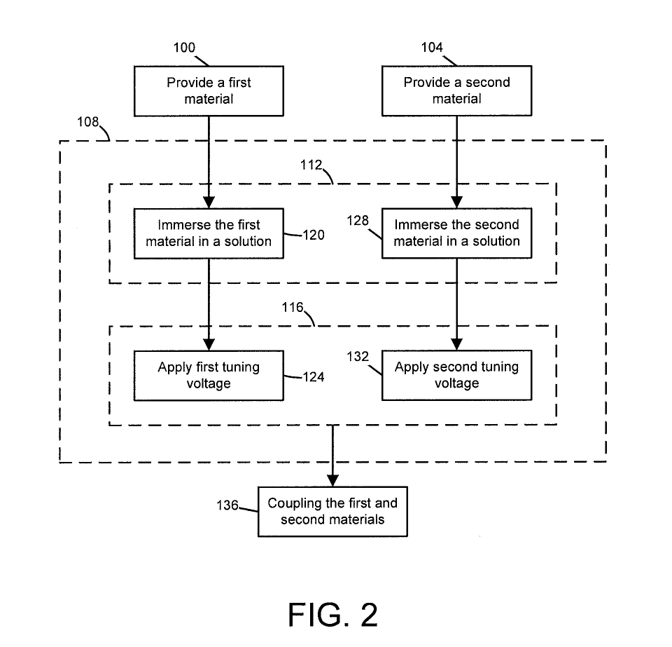

Referring now to FIG. 2, a flowchart is shown depicting on exemplary method of making tunable diode 10. In the embodiment illustrated, the method comprises, at step 100, providing a first material (e.g., first material 14) that is configured to be dopable electrochemically, and can comprise an anion and a cation, where one of the anion and cation is immobile, and the other of the anion and cation is mobile. The embodiment illustrated further comprises, at step 104, providing a second material (e.g., second material 18) that is configured to be dopable electrochemically. In some embodiments, one or both of steps 100 and 104 can comprise making a first material and/or a second material, respectively, such as, for example, by the methods listed below in the Example 1. The embodiment illustrated also comprises block 108 in which, at block 112, one or both of the first and second materials is immersed in a solution and/or, at block 116, a tuning voltage is applied to one or both of the first and second materials. More particularly, the embodiment illustrated comprises, at step 120, immersing the first material in a solution; and, at step 124, applying a first tuning voltage potential across the first material while the first material is immersed in the solution, where the first tuning voltage potential is sufficient to modify the electrochemical potential of the first material. The embodiment illustrated further comprises, at step 128, immersing the second material in a solution; and, at step 132, applying a second tuning voltage potential across the second material while the second material is immersed in the solution, where the second tuning voltage potential is sufficient to modify the electrochemical potential of the second material The embodiment illustrated further comprises, at step 136, coupling the first material to the second material such that if a sufficient voltage potential is applied across the coupled first and second materials: (1) at least a portion of the mobile one of the anion and cation migrates from the first material to the second material such that p-doping of one of the first and second materials increases and n-doping of the other of the first and second materials increases; and (2) the conductivity increases across the coupled first and second materials.

In some embodiments, block 112 comprises immersing only the first material in a solution and block 116 comprises applying only a first tuning voltage potential to the first material. In some embodiments, block 112 comprises immersing only the second material in a solution and block 116 comprises applying only a second tuning voltage potential to the second material. In some embodiments, block 108 is omitted entirely such that the method comprises providing a first material (e.g., first material 14); providing a second material (e.g., material 18); and coupling the first material to the second material. In other embodiments, the method comprises only step 136, i.e., coupling a first material (e.g., first material 14) to a second material (e.g., second material 18).

The following example is included to demonstrate an embodiment of the present methods and apparatuses. Those of skill in the art should, in light of the present disclosure, appreciate that many changes can be made in the specific embodiments disclosed in these examples and still obtain a like or similar result without departing from the scope of the invention.

### Example 1

### Preparation of IDA/PT⁺(DS⁻) Film

Initial experimental data for PT⁺(DS⁻) was gathered from PT⁺(DS⁻) film on an interdigital array (IDA) electrode. Gold IDAs were obtained from Biomedical Microsensors Laboratory at North Carolina State University. For brevity, the process for a single IDA electrode is described here. The gold IDA array contained 2.8 mm×0.075 mm gold electrodes with a gap width of 20 micrometers (μm) that had a total exposed area of 6.09 mm². Electrochemical polymerization of PT⁺(DS⁻) films were built on an IDA electrode from a binary dispersion of 2,2′-bithiophene (0.1M) and DS (0.1M) in a water/acetonitrile mix (volume ration 1:1) at a constant potential of +0.9 V vs. Ag/AgCl. To achieve a completely bridged film and to control the thickness of the polymer film, a 1.03 C cm⁻² charge was passed through the IDA electrode. The resulting film thickness was estimated at about 10 μm. All electrochemical measurements and depositions were carried-out utilizing a CHI660 or CHI760 workstation (CH Instruments, U.S.A.) and, prior to electrochemical measurements, solutions were purged with nitrogen and electrodes were cleaned with 0.5M H₂SO₄. A standard three-electrode arrangement was adopted with the IDA or ITO working electrode, a platinum (Pt) counter electrode and an Ag/AgCl reference electrode. For all electrochemical measurements, the scan rate was 0.02 Vs⁻¹, unless otherwise indicated.

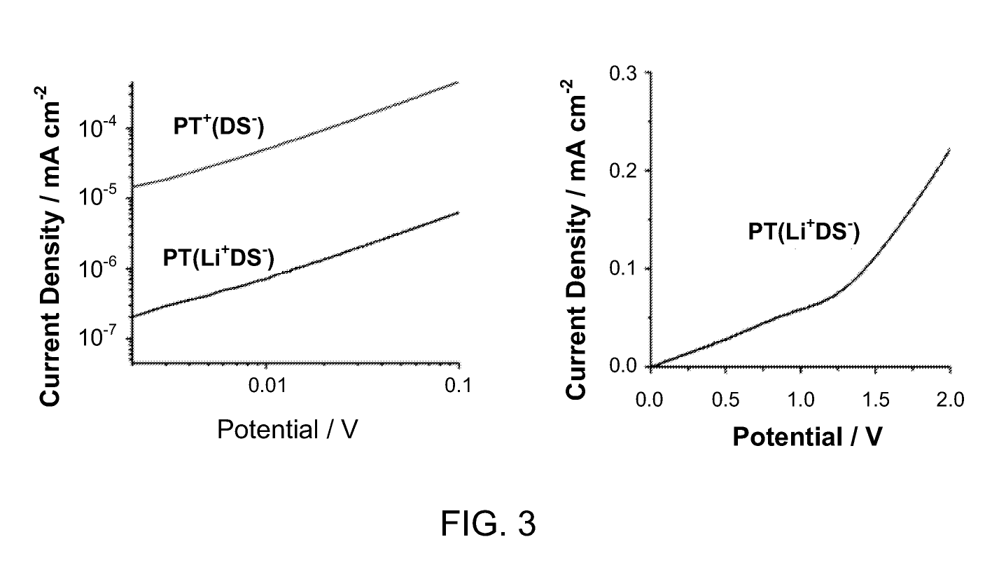

FIG. 3 depicts current voltage behavior of PT⁺(DS⁻) composite on an IDA electrode in the oxidized state as grown prior to reduction (upper line) and after reduction with Li⁺ incorporated in the film (lower line), at a scan rate of 0.1 mVs⁻¹. During the electrochemical deposition of the PT⁺(DS⁻) film on IDA electrodes, a total charge was passed of 1.03 C cm⁻². The PT⁺(DS⁻) film was reduced with 0.1M LiClO₄ in propylene carbonate for 10 minutes and the total charge was reduced 0.41 C cm⁻². The right graph in FIG. 3 depicts the current voltage behavior of PT⁺(Li⁺DS⁻) across a range of voltage potential.

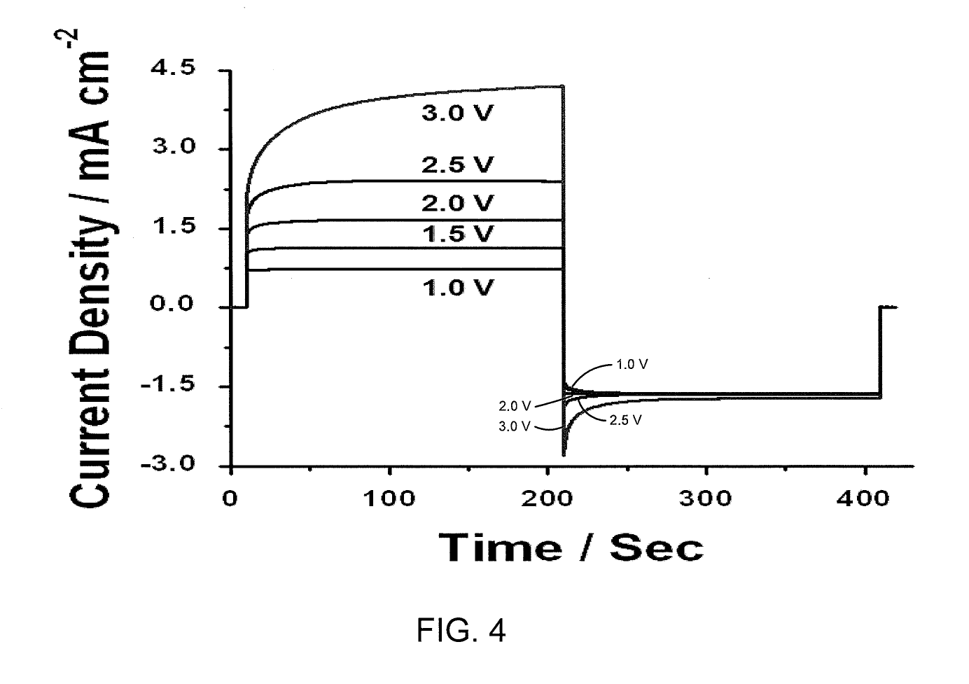

FIG. 4 depicts multi-potential steps curves of PT⁺(DS⁻) on an IDA electrode. The device's behavior can be explained by field generation of a conducting region. The current increased as the applied potential was increased. Behavior also varied with time, possibly due to the formation of asymmetry in the junction.

### Fabrication of ITO/PT⁺(DS⁻) and ITO/WO₃ Films:

To prepare the ITO/PT⁺(DS⁻) film, slides of indium tin oxide (ITO) coated glass (6±2 Ω/squire, 5.0 cm×0.7 cm in size) were cleaned in piranha solution (3:1 mixture of H₂SO₄ and H₂O₂); sonicated in ultrapure water, acetone, and ethanol, consecutively; and dried in an N₂ stream. The area of the working electrode ITO exposed to the electrolyte solution was 1.8 cm×0.7 cm (1.26 cm²). To achieve a PT⁺(DS⁻) film with a 10 μm thickness, a constant potential of +0.9 V vs. Ag/AgCl was applied and a total charge of 1.03 C cm⁻² was passed on the ITO electrode.

To prepare the ITO/WO₃ film, stock peroxi-polytungstate deposition solution was prepared by dissolving 1 gram (g) of tungsten powder in 5 ml of 30% H₂O₂ at 0° C. for 24 h. Upon complete dissolution of the metal, the solution was filtered and diluted with ultrapure water to produce 50 mM tungsten solution. The excess H₂O₂ was decomposed using a temperature-controlled (10° C.) sonication bath (117 W) for 6 hrs. Previously cleaned ITO electrodes (1.26 cm²) were immersed in peroxi-polytungstate solution and WO₃ was by electrochemical deposition at a constant potential of −0.5 V vs. Ag/AgCl (at a reference electrode). A total charge of 1.03 C cm⁻² was passed through the ITO electrode to prepare a 260 nm thickness film. The resulting deep-blue-colored films were copiously washed in ultrapure water and then baked at 120° C. for 24 hours. After baking, the films were semitransparent in color.

### Fabrication of Heterojunction of PT(Li⁺DS⁻)|WO₃:

Heterojunctions consisting of polythiophene (PT) containing lithium dodecylsulfate (Li⁺DS⁻) and tungsten oxide (WO₃) were created via constant potential electrodeposition.

To determine the I-V characteristics of PT(Li⁺DS⁻)|WO₃ heterojunctions in solution and solid states, WO₃ and PT⁺(DS⁻) films were reduced and oxidized by applying −1.0 V anodic and +1.2 V cathodic potentials, respectively. In both processes, +2 V forward potential was applied to the PT⁺(DS⁻) with respect to the WO₃ in 0.1 M LiClO₄ PC solution. The current was obtained due to Faradaic process (without direct contact), and in solid state (with direct contact). The estimated current is the sum of Faradaic and DC currents. To determine the tunable diode property of the PT(Li⁺DS⁻)|WO₃ heterojunction, potentials of 0.0, −0.2, −0.4, and −0.6 V, respectively, were applied to the PT⁺(DS⁻) and WO₃ in 0.1 M LiClO₄ propylene carbonate (PC) solution. The resulting modified PT⁺(DS⁻) and WO₃ films were sandwiched together (traces of electrolyte solution may have remained on the surfaces), and +2.0 V forward bias was applied to the PT⁺(DS⁻) with respect to the WO₃, and I-V behavior was determined. In order to obtain reliable comparisons, the thickness of the PT⁺(DS⁻) and WO₃ films were kept practically unchanged at 10 μm and 360 nm respectively for each of heterojunctions examined.

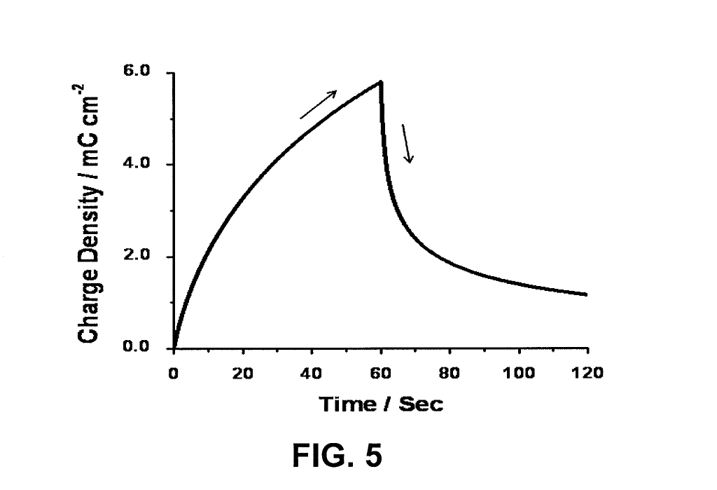

FIG. 5 depicts the charging and discharging properties of the PT(Li⁺DS⁻)|WO₃ heterojunction by chronoamperometry in 0.1 M LiClO₄ propylene carbonate solution. The charge increased steadily when 2 V potential was applied to PT⁺(DS⁻) with respect to WO₃, and at 0 V it was almost discharged.

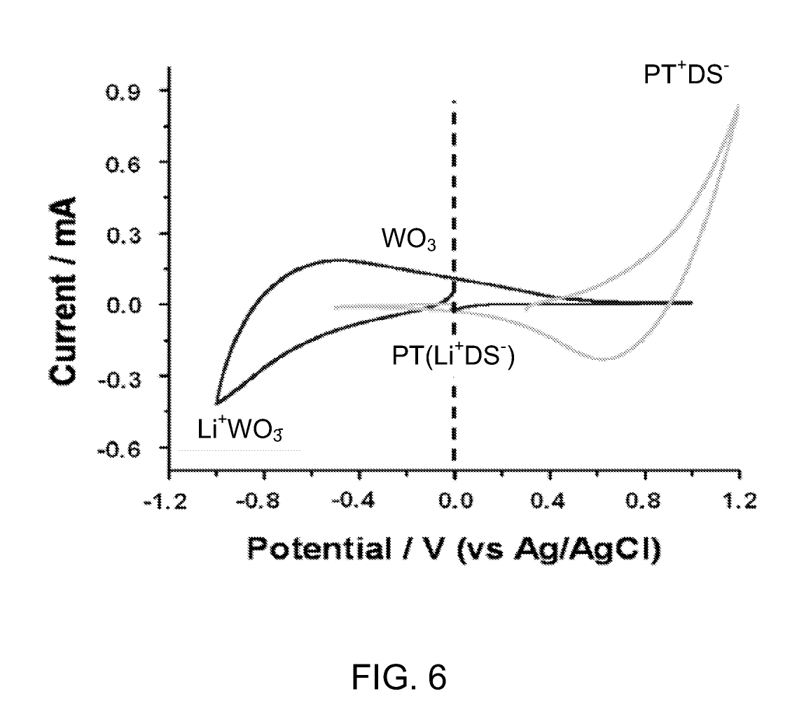

FIG. 6 depicts the voltammetric response of PT⁺(DS⁻) (gray line) and WO₃ (black line) thin films on ITO electrodes immersed in 0.1 M LiClO₄ propylene carbonate solution. The scan rate was 0.02 Vs⁻¹.

FIG. 6 illustrates the redox (reduction-oxidation reaction) behavior of each component (polymeric layer 14 and oxide layer 18), in which PT(Li⁺DS⁻) undergoes oxidation (p-doping) and an almost 2 order of magnitude increase in conductivity (as also illustrated in FIG. 3 and FIG. 4, above) at potentials positive of +0.4 V vs. Ag/AgCl; while WO₃ remains undoped and relatively insulating within this potential window. In contrast, WO₃ undergoes reduction (n-doping) and an increase in conductivity at potentials negative of −0.4 V vs. Ag/AgCl, where PT(Li⁺DS⁻) remains undoped and relatively insulating. By immobilizing DS″ within the polymer and requiring the movement of Li⁺ to maintain charge neutrality for both materials it is possible to create a system where the drift of Li⁺ between PT(Li⁺DS⁻) and WO₃ results in the in situ doping of both materials in the solid state and in turn the reversible formation of a p/n junction in forward bias. Reversal of the bias results in the return of Li⁺ across the junction and the formation of the undoped, insulating components. This results in rectification through changing conductivity in the solid-state for conducting polymers in solution.

The Faradaic processes responsible for doping in both materials can be investigated in the absence of the non-Faradaic current flowing through the junction, such as, for example, by separating the two halves of the junction and performing a two-electrode experiment in an electrolyte solution containing Li⁺. This can then be compared to the current observed passing through the junction when the two halves are placed in contact.

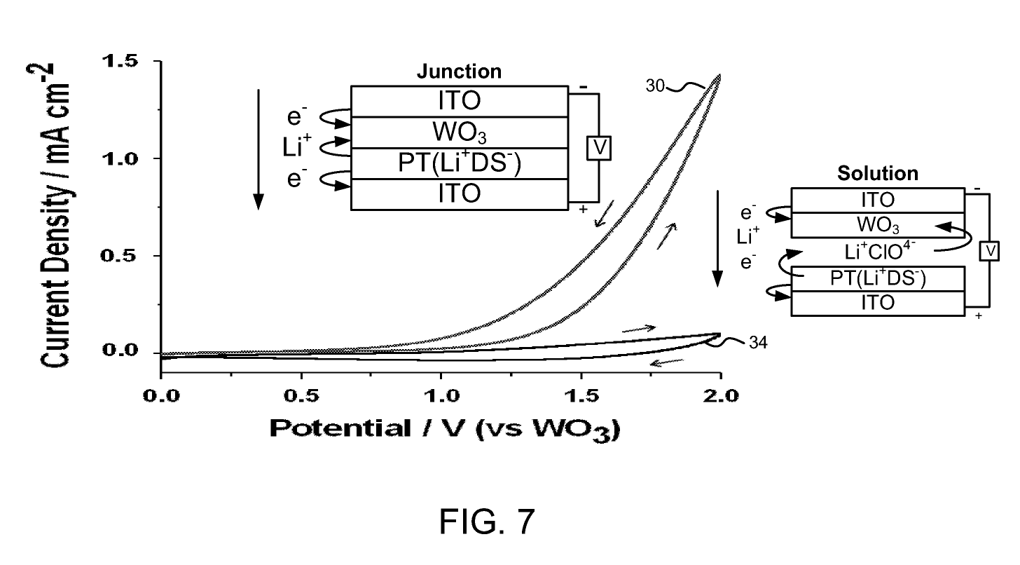

FIG. 7 depicts current passing through the PT(Li⁺DS⁻)|WO₃ heterojunction in direct contact under nitrogen (curve 30), and without direct contact in 0.1M LiClO₄ propylene carbonate solution (curve 34). The bias was applied to PT(Li⁺DS⁻) as shown, with a scan rate of 0.02 Vs⁻¹. Arrows indicate direction of the scan.

FIG. 7 illustrates the voltammetry of the system in a two electrode configuration where the electrochemical potential of both materials have been set initially to 0 V vs Ag/AgCl (i.e., both are undoped—see FIG. 1); and, as shown, the potential of PT(Li⁺DS⁻) is scanned positive with respect to WO₃, which is scanned negative. In this configuration, when the electrodes are in solution, electrons flow through the external circuit and Li⁺ flows through solution from PT(Li⁺DS⁻) to WO₃ as illustrated in FIG. 7. Removal of the electrodes and creation of a junction by compressing the two halves together allows the flow of current associated with both the Faradaic process as well as the field driven current passing through the junction. As can be seen in FIG. 7, the formation of a contact junction results in a dramatic increase in current associated with the doping process and the resulting increase in conductivity through the junction.

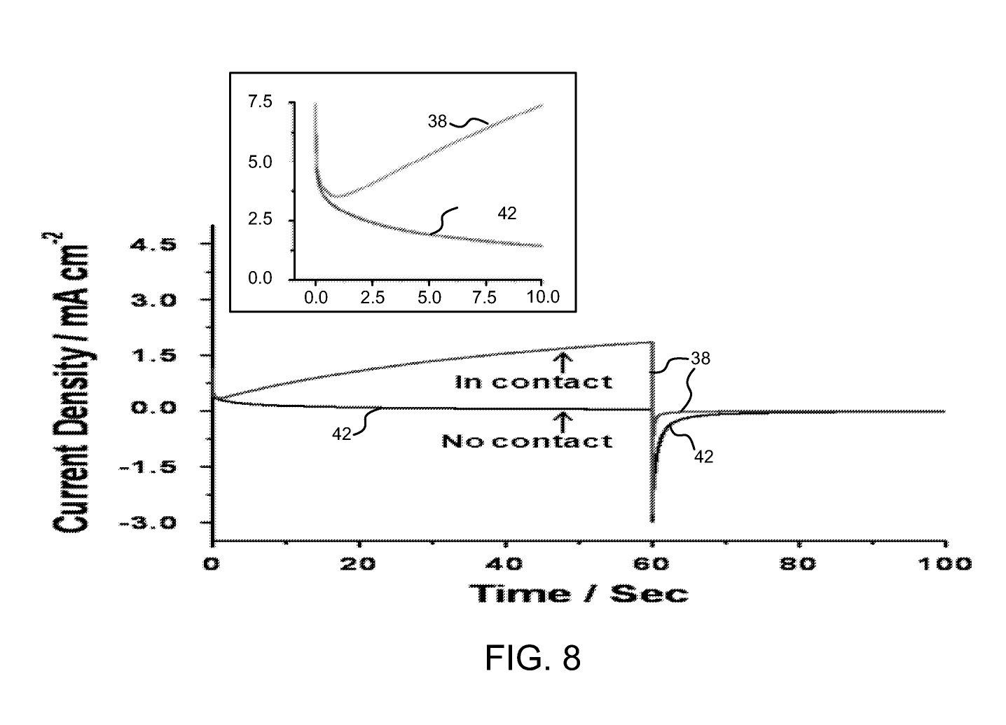

FIG. 8 depicts temporal behavior of a PT(Li⁺DS⁻)|WO₃ heterojunction due to the drifting of Li⁺ across the junction in direct contact in solid-state (curve 38), and without direct contact in 0.1 M LiClO₄ propylene carbonate solution (curve 42). The bias was applied to PT(Li⁺DS⁻) with respect to WO₃, as in FIG. 7 (positive electrode to PT(Li⁺DS⁻). The insert shows the enlarged view of curves 38 and 42, and depicts the evolution of current over the first ten seconds after the potential step was applied.

The temporal behavior associated with the drift of Li⁺ across the interface can be observed with, for example, chronoamperometry, as seen in FIG. 8. Upon applying a potential step of +2 V, the current drops significantly over the first 2 seconds (see inset) and is dominated by the Faradaic process due to the relatively low conductivity of the materials in the junction. This is followed by a gradual increase in current associated with increasing conductivity and the associated field driven current. On the return step, the discharging associated with the Faradaic process and return of the Li⁺ is clearly observed in (solid) state and the total charge passed is almost equal. However, the solid-state junction shows a much more rapid decay in the current on the reverse step and a smaller total charge. This suggests that in the solid-state junction, both Li⁺ and electrons cross the interface, thereby reducing the total charge observed through the external circuit.

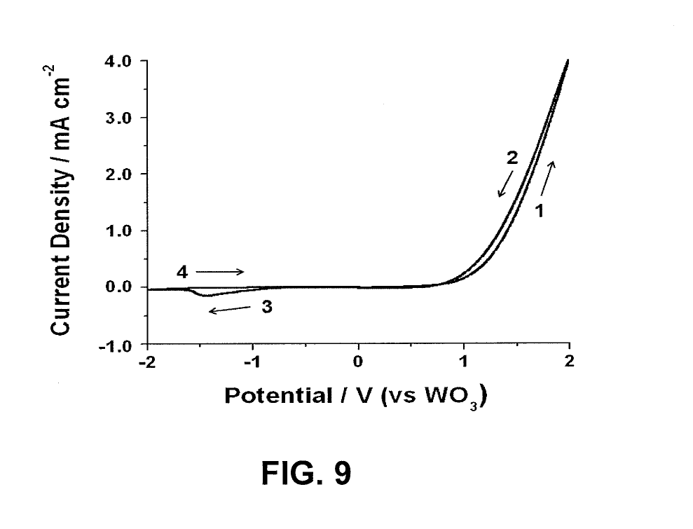

FIG. 9 depicts current density as a function of applied bias for the PT(Li⁺DS⁻)|WO₃ heterojunction in direct contact. Numbers and arrows indicate the scan sequence beginning at 0 V and O mA/cm². The scan rate was 0.02 Vs⁻¹

FIG. 9 illustrates the current-voltage (I-V) diode behavior of a heterojunction. The current density under negative bias is more than 3.0 orders of magnitude lower than that in the forward. This indicates that the drift of cations in the polymer, away from the polymer|metal oxide interface, leads to a buildup of a negative space charge region in contact with a relatively insulating wide band gap intrinsic semiconductor. Varying the voltage scan rate had a significant effect on the I-V behavior and is likely due to the Li⁺ ion movement through the junction. All the I-V measurements were carried-out under nitrogen atmosphere at room temperature and the stability of the heterojunction was monitored for weeks without significant degradation.

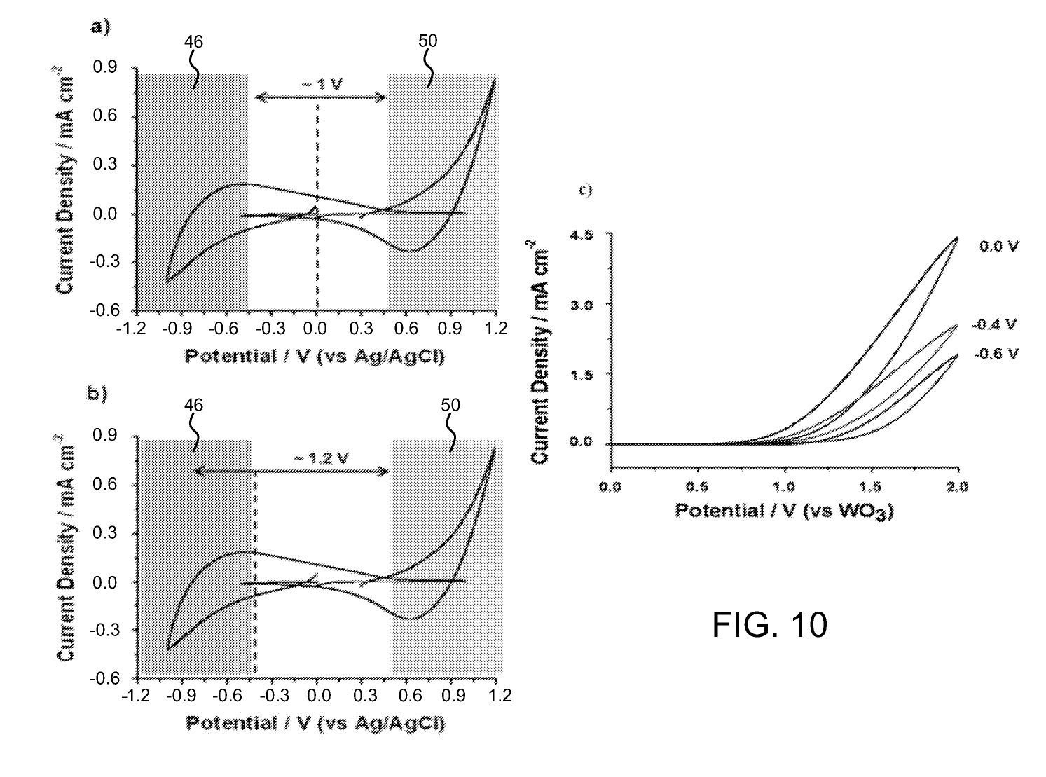

FIG. 10 depicts current density behavior of a PT(Li⁺DS⁻)|WO₃ tunable diode as a function of applied bias to PT(Li⁺DS⁻) with respect to WO₃. The three curves illustrate the applied potentials of 0.0 V, −0.4 V and −0.6 V, respectively, vs Ag/AgCl. The boxes 46 and 50 illustrate the potential at which the polymer and oxide reach and/or exhibit a conductive state. Inset a) indicates that 1 V potential is sufficient to make the polymer and oxide conductive. Inset b) indicates that about ˜1.2 V potential was required to achieve the negative bias (−0.4 V vs Ag/AgCl) shift in the Fermi level and to get the polymer into a conducting state. The scan rate was 0.02 Vs⁻¹

One characteristic of using semiconducting materials can be that the doping level, and in turn the Fermi level, can be altered electrochemically such that the performance of electronic devices can be easily tuned even after device fabrication. FIG. 10 demonstrates this behavior for the PT(Li⁺DS⁻)|WO₃ junction described herein. For example, by changing the electrochemical potential of both halves of the heterojunction from 0.0 (FIG. 10a) to −0.4 V (FIG. 10b) vs. Ag/AgCl in solution (3-electrode no-direct-contact configuration) prior to creating the junction and subsequently measuring the I-V curve (2-electrode direct-contact configuration), the bias required to induce the drift of Li⁺ and convert both halves to their doped conducting states is increased, thereby increasing the apparent threshold voltage. A smaller change in potential of the WO₃ electrode from −0.4 V relative to PT(Li⁺DS⁻) (see FIG. 10b) may be required because the doping process begins at a smaller potential excursion in the case of WO₃ and the effective capacitance of the WO₃ electrode may be larger.

### UV-Vis-Spectroscopy:

UV-vis spectroscopy was acquired at room temperature on an Agilent 8453 UV-vis-Spectrometer. Prior to the measurements, the electrolyte (0.1M LiClO₄/PC) was thoroughly degassed by bubbling with N₂ gas, and the cell was maintained under a blanket of N₂ through all measurements.

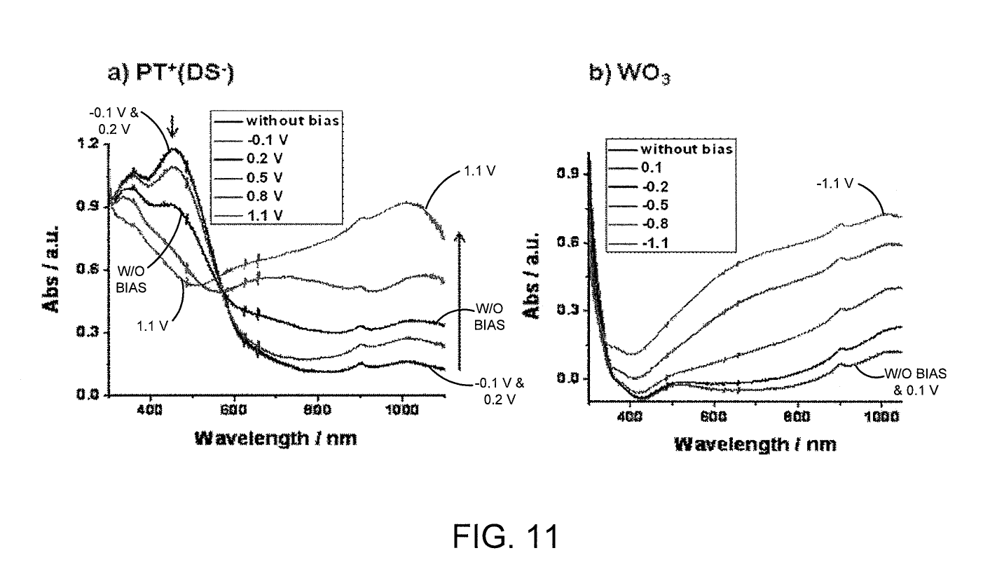

FIG. 11 depicts the measured UV-vis spectra of (a) PT⁺(DS⁻) film that was subjected to oxidation-inducing positive potentials in steps between, and (b) WO₃ film that was subjected to reduction-inducing negative potentials in steps. All the films of PT⁺(DS⁻) were applied to ITO electrodes by electrochemical deposition, and a total charge of 1.03 C cm⁻² was passed through the respective electrode. The PT⁺(DS⁻) film was reduced with 0.1 M LiClO₄ in propylene carbonate for 10 minutes, and the total charge was reduced 0.41 C cm⁻².

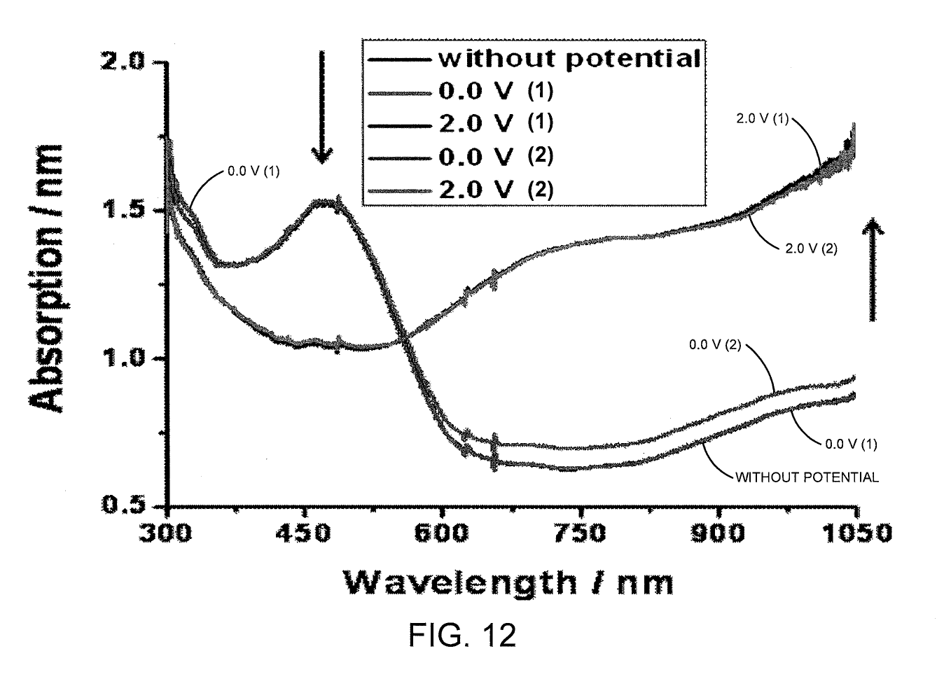

FIG. 12 depicts the UV-vis spectra of sandwich film of PT(Li⁺DS⁻)|WO₃ under different potentials. Prior to the measurements, PT⁺(DS⁻) was reduced (reduction potential 0.3 V and total charge was reduced to 0.41 C cm⁻²) with 0.1 M LiClO₄ in propylene carbonate solution. The optical density of PT(Li⁺DS⁻)|WO₃ was increased from 550 nm to 1050 nm, a broad and new absorption band appeared after application of 2.0 V potential, and the characteristic absorption band of PT⁺(DS⁻) at 450 nm disappeared completely. Arrows indicate the direction of spectral changes with potential.

The various illustrative embodiments of devices, systems, and methods described herein are not intended to be limited to the particular forms disclosed. Rather, they include all modifications, equivalents, and alternatives falling within the scope of the claims.

The claims are not intended to include, and should not be interpreted to include, means-plus- or step-plus-function limitations, unless such a limitation is explicitly recited in a given claim using the phrase(s) “means for” or “step for,” respectively.

### REFERENCES

The following references, to the extent that they provide exemplary procedural or other details supplementary to those set forth herein, are specifically incorporated herein by reference.
[1] D. J. Frank, R. H. Dennard, E. Nowak, P. M. Solomon, Y. S. Wong, Proc. IEEE, 2001, 89, 259. b) K. K. Likharev, in Nano and Giga Challenges in Microelectronics (eds J. Greer, A. Korkin and J. Labanowski) 27-68 (Elsevier, Amsterdam, 2003).
[2] S. Tehrani, J. M. Slaughter, M. Deherrera, B. N. Engel, N. Rizzo, J. Salter, M. Durlam, R. W. Dave, J. Janesky, B. Butcher, K. Smith, G. Grynkewich, Proc. IEEE, 2003, 91, 703.
[3] G. R. Fox, F. Chu, T. Davenport, Vac. Sci. Technol. B, 2001, 19, 1967.
[4] J. H. Burroughes, D. D. C. Bradley, A. R. Brown, R. N. Marks, K. Mackay, R. H. Friend, P. L. Burns, A. B. Holmes, Nature, 1990, 347, 539.
[5] F. Garnier, R. Hajlaoui, A. Yassar, P. Srivastava, Science, 1994, 265, 1684. Transistor, N. Tessler, G. J. Denton, R. H. Friend, Nature, 1996, 382, 695.
[6] M. Granstrom. K. Petritsch, A. C. Arias, A. Lux, M. R. Anderson, R. H. Friend, Nature, 1998, 395, 257.
[7] H. Goto, E. Yashima, J. Am. Chem. Soc. 2002, 124, 7943.
[8] C. H. W. Chiang, M. C. Lonergan, M. C. J. Am. Chem. Soc. 2004, 126, 10536.
[9] P. M. Grant, T. Tani, W. D. Gill, M. Krounbi, T. C. Clarke, J. Appl. Phys. 1981, 52, 869.
[10] S. C. K. Misra, M. K. Ram, S. S. Pandey, D. B. Malhotra, S. Chandra, Appl. Phys. Lett. 1992, 61, 1219.
[11] S. Aydo [symbol] an, M. Sa [symbol] lam, A. Türüt Polymer, 2005, 46, 563.
[12] R. Singh, A. K. Narula, Appl. Phys. Lett. 1997, 71, 2845.
[13] K. Kaneto, K. W. Takashima, Current Appl. Phys. 2001, 1, 355.
[14] M. J. Sailor, F. J. Klavetter, R. H. Grubbs, N. S. Lewis, Nature, 1990, 346, 155.
[15] L. M. Huang, T. C. Wen, A. Gopalan, Thin Solid Films 2005, 473, 300.
[16] F. E. Jones, B. P. Wood, J. A. Myer, C. D. Hafer, M. C. Lonergan, J. Appl. Phys. 1999, 86, 6431.
[17] S. W. Boettcher, N. C. Strandwitz, M. Schierhorn, N. Lock, M. C. Lonergan, G. Stucky, Nature Materials 2007, 6, 592.
[18] B. A. Korgel, Nature Materials 2007, 6, 551.
[19] http://resolver.caltech.edu/CaltechETD:etd-10262007-085203
[20] M. S. Freund, C. Karp, N. S. Lewis, Inorg. Chim. Acta 1995, 240, 447.
[21] L. Brillson, J. Surf Sci. Rep., 1982, 2, 123.
[22] S. M. Sze, Physics of Semiconductor Devices, Wiley, New York, 1981, 245
[23] M. C. Lonergan, Science 1997, 278, 2103.
[24] M. S. Freund, C. Karp, N. S. Lewis, Inorg. Chim. Acta 1995, 240, 447.
[25] D. J. Dick, A. J. Heeger, Y. Yang, Q. Pei, Adv. Mat. 1996, 8, 985.
[27] R. G. Pillai, J. H. Zhao, M. S. Freund, D. J. Thomson, Adv. Mater. 2008, 20, 49.
[28] S. Barman, F. Deng, R. L. McCreery, J. Am. Chem. Soc. 2008, 130, 11073.
[29] C. G. Granqvist, Handbook of Inorganic Electrochromic Materials, 1st ed.; Elsevier: Amsterdam, 1995.
[30] M. N. Kozicki, C. Gopalan, M. Balakrishnan, M. Mitkova, IEEE Trans. Nanotechnol. 2006, 5, 535.
[31] M. Gillet, K. Aguir, C. Lemire, E. Gillet, Schierbaum, K. Thin Solid Films 2004, 467, 239.
[32] R. C. Agrawal, M. L. Verma, R. K. Gupta, Solid State Ionics 2004, 171, 199.
[33] R. G. Pillai, J. H. Zhao, M. S. Freund, D. J. Thomson, Adv. Mater. 2008, 20, 49
[34] H. S. White, G. P. Kittlesen, M. S. Wrighton, J. Am. Chem. Soc. 1984, 106, 5375.
[35] D. OFER, R. M. CROOKS, M. S. WRIGHTON, J. AM. CHEM. SOC. 1990, 112, 7869.

1. A tunable diode comprising:
a first material configured to be dopable electrochemically, the first material comprising an anion and a cation, where one of the anion and cation is immobile, and the other of the anion and cation is mobile;
a second material coupled to the first material, the second material configured to be dopable electrochemically;
where the first material and second material are configured such that if a sufficient voltage potential is applied across the first material and second material:
at least a portion of the mobile one of the anion and cation migrates from the first material to the second material such that p-doping of one of the first and second materials increases and n-doping of the other of the first and second materials increases; and
the conductivity increases across the coupled first and second materials.

2. The diode of claim 1, where the first material comprises a semiconducting polymer.

3. (canceled)

4. The diode of claim 2, where the second material comprises an oxide.

5. (canceled)

6. (canceled)

7. (canceled)

8. (canceled)

9. (canceled)

10. (canceled)

11. (canceled)

12. The diode of claim 1, where the second material is in contact with the first material.

13. The diode of claim 1, where at least one of the first and second materials is not doped in the absence of a voltage potential.

14. The diode of claim 13, where both of the first and second materials are not doped in the absence of a voltage potential.

15. (canceled)

16. The diode of claim 1, where one of the first and second materials is n-doped in the absence of a voltage potential.

17. The diode of claim 16, where the other of the first and second materials is p-doped in the absence of a voltage potential.

18. A method of making a tunable diode, the method comprising:
providing a first material configured to be dopable electrochemically, the first material comprising an anion and a cation, where one of the anion and cation is immobile, and the other of the anion and cation is mobile;
immersing the first material in a liquid solution;
applying a first tuning voltage potential across the first material while the first material is immersed in the solution, the first tuning voltage potential sufficient to modify the electrochemical potential of the first material;
providing a second material configured to be dopable electrochemically; and
coupling the first material to the second material such that if a sufficient voltage potential is applied across the coupled first and second materials:
at least a portion of the mobile one of the anion and cation migrates from the first material to the second material such that p-doping of one of the first and second materials increases and n-doping of the other of the first and second materials increases; and
the conductivity increases across the coupled first and second materials.

19. The method of claim 18, where the first material comprises a semiconducting polymer.

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. The method of claim 18, where in the coupling, the second material is coupled to the first material such that the second material is in contact with the first material.

33. The method of claim 18, where the solution comprises the mobile of one of the anion and cation of the first material.

34. The method of claim 18, where the coupling is performed prior to immersing or applying a voltage to the first material.

35. The method of claim 18, further comprising:
immersing the second material in a liquid solution; and
applying a second tuning voltage potential across the second material while the second material is immersed in the solution, the second tuning voltage potential sufficient to modify the electrochemical potential of the second material.

36. The method of claim 35, where the coupling is performed prior to immersing or applying a voltage to either of the first material or the second material.

37. The method of claim 35, where after applying the tuning voltage potential across the first and second materials, at least one of the first and second materials is not doped in the absence of a voltage potential.

38. (canceled)

39. The method of claim 35, where after applying the first tuning voltage potential across the first material and applying the second tuning voltage potential across the second material, one of the first and second materials is p-doped in the absence of a voltage potential.

40. The method of claim 35, where after applying the first tuning voltage potential across the first material and applying the second tuning voltage potential across the second material, one of the first and second materials is n-doped in the absence of a voltage potential.

41. The method of claim 40, where after the first tuning voltage potential across the first material and applying the second tuning voltage potential across the second material, the other of the first and second materials is p-doped in the absence of a voltage potential.

42. (canceled)

43. (canceled)

44. (canceled)

45. A method of making a tunable diode, the method comprising:
providing a first material configured to be dopable electrochemically, the first material comprising an anion and a cation, where one of the anion and cation is immobile, and the other of the anion and cation is mobile;
providing a second material configured to be dopable electrochemically;
coupling the first material to the second material such that if a sufficient voltage potential is applied across the coupled first and second materials:
at least a portion of the mobile one of the anion and cation migrates from the first material to the second material such that p-doping of one of the first and second materials increases and n-doping of the other of the first and second materials increases; and
the conductivity increases across the coupled first and second materials.

46. (canceled)
